(19) United States
(12) Patent Application Publication
(10) Pub. No.: US 2006/0225638 A1
(43) Pub. Date: Oct. 12, 2006

(54) Process for the low-temperature joining of bodies, and products produced in accordance with the process

(75) Inventors: Esemann Hauke, Worrstadt (DE); Carol Click, Duryea, PA (US); Eva Hoelzel, Ober-Olm (DE)

Correspondence Address: Charles N.J. Ruggiero;Ohlandt, Greeley, Ruggiero & Perle, L.L.P., 10th Floor, One Landmark Square, Stamford, CT, 06901-2682, US

(73) Assignee: SCHOTT AG

(21) Appl. No.: 11/325,406

(22) Filed: Jan. 4, 2006

(30) Foreign Application Priority Data
Jan. 5, 2005 (DE) 10 2005 000 865.8

(51) Int. Cl. H01L 21/322

(52) U.S. Cl. 117/2

(57) ABSTRACT

To bond bodies with a high thermal stability, a process is provided for bonding two bodies, in which the bodies are joined together using an aluminate-containing solution, and constituents of the aluminate-containing solution are made to react between those surfaces of the bodies which have been joined together.

### CROSS REFERENCE TO RELATED APPLICATIONS

This application claims benefit under 35 U.S.C. §119 of German Patent Application No. 10 2005 000 865.8, filed Jan. 5, 2005, the entire contents of which are incorporated herein by reference.

### BACKGROUND OF THE INVENTION

1. Field of the Invention

The invention relates in general terms to the technique for bonding bodies which is generally known as low-temperature bonding (LTB). In particular, the invention relates to a process for joining together bodies by means of this technique and to products producible by the process.

2. Description of Related Art

The technique of joining together bodies which is generally known as low-temperature bonding, in which two surfaces of the bodies to be bonded are joined together using a suitable solution, producing a fixed bond between the bodies as a result of a chemical reaction between the interfaces of the bodies and constituents of the solution, is known from the prior art. This process is used inter alia to join together glass bodies in optical applications. In the context of the present invention, the term low-temperature bonding is to be understood as meaning bonding which is produced at a low temperature, i.e. typically from room temperature to approximately 100° C., between at least two bodies that are to be joined.

The most widespread process in this context is joining by means of a silicate-containing solution, usually comprising sodium silicate. In this case, during the reaction, a silicon/oxygen network is formed, producing a stable bond between the bodies. Bonds of this type are known, for example, from WO 97/43117. U.S. Pat. No. 6,284,085 B1 likewise describes the bonding of surfaces by forming hydroxyl groups at the surface and the use of a silicate filler material to bond quartz glass.

For some applications, however, it is desirable for it to be possible to provide a bond which is more thermally stable than these known bonds produced at low temperature.

### BRIEF SUMMARY OF THE INVENTION

This object is achieved, in a very surprisingly simple way, by the subject matter of the present disclosure.

Accordingly, the invention provides a process for bonding two bodies in which the bodies are joined together using an aluminate-containing solution, and constituents of the aluminate-containing solution are made to react between those surfaces of the bodies which have been joined together.

In this way, in accordance with the invention, a product with at least two bonded bodies is obtained, in which in each case one surface of a body is bonded to a surface of another body by means of an aluminum/oxygen network.

The process makes it possible to use a low-temperature process to create bonds which are significantly more thermally stable than what it has been possible to achieve using previously customary LTB processes based generally on the use of silicates. The aluminum/oxygen network which forms has melting points similar to those of a sapphire crystal of more than 200° C.

In this context, it has surprisingly been discovered that even an aluminate-containing solution is suitable for the low-temperature bonding of bodies. It is in this context preferable to use a tetrahydroxyaluminate-containing solution during the joining. Although tetrahydroxyaluminate could be regarded as an intermediate for the orthosilicate, which is contained in many known solutions for low-temperature bonding, in the case of the orthosilicate the negative charge is located on an oxygen atom, whereas in the tetrahydroxyaluminate the aluminum bears the negative charge. It is therefore not obvious that the tetrahydroxyaluminate will react in the same way. Unlike orthosilicate, moreover, the tetrahydroxy-aluminate is in equilibrium with Al(OH)₃ and OH⁻. This gives rise to the problem compared to the orthosilicate of stabilizing the tetrahydroxyaluminate in the solution.

In this respect, it has also surprisingly been discovered that the aluminate in the solution can be stabilized using a base. This measure is not required in standard bonding solutions. Despite the use of a base in the solution, however, it is surprisingly possible to obtain extremely stable low-temperature bonds. Despite the presence of the base, a stable aluminum/oxygen network is formed, the strength of which is not affected or at least is not significantly affected by the presence of the base. In this context, a sodium aluminate solution stabilized with sodium hydroxide has proven to be a particularly favorable formulation.

In the context of the present invention, the term low-temperature bonding or “LTB” is to be understood as meaning that the bodies are joined together using a solution temperature which is below the boiling point. It is preferable for the joining to take place at room temperature or temperatures less than 100° C. The joining operation is followed by the chemical reaction with solution constituents, which is likewise preferably carried out at low temperatures, in particular in the range up to 200° C., particularly preferably up to 100° C., in particular at room temperature.

Both the optical quality and the strength of the bond is influenced to a decisive extent by the surface condition of those surfaces of the bodies which are to be joined. The flatter the surface of the bodies, the better the bond. Accordingly, it is preferable for polished surfaces of the bodies to be joined to one another. For example, it is expedient to use polished body surfaces which have a flatness of better than 1 micrometer, preferably better than 200 nm. A low flatness is also advantageous for a high quality of bond.

Furthermore, it has surprisingly also emerged that the optical quality and strength of a low-temperature bond, in particular also of a bond with an aluminum/oxygen network, is dependent on the presence of carbon dioxide in the surrounding atmosphere. It has been found that carbon dioxide, or the carbonic acid which forms in the solution, has a highly deleterious effect on the bond. Accordingly, an advantageous refinement of the invention provides for the joining and/or the chemical reaction to be carried out in a low-carbon dioxide atmosphere. A low-carbon dioxide atmosphere is to be understood as meaning an atmosphere which contains no more carbon dioxide, and in particular less carbon dioxide, than the normal ambient air. More carbon dioxide than in the ambient air may occur for example during cleaning of the bodies with carbon dioxide snow.

The process is particularly preferably used for the production of products with at least one body containing aluminum oxide. It is in this way possible to create a product in which the bond which forms in accordance with the invention using an aluminum/oxygen network may have the same or similar condition to the body, in particular with regard to the strength, thermal stability and refractive index. According to a refinement of the invention, at least one sapphire body is joined to another body, for example another sapphire body or an aluminum oxide ceramic. For example, according to one embodiment of the invention, a plurality of sapphire crystals can be bonded using an aluminate-containing solution in accordance with the low-temperature bonding of the invention to form a larger crystal.

However, it is also possible to use bodies comprising other materials. By way of example, the process is also suitable for the high-strength bonding of a glass or glass-ceramic body or of crystalline materials. According to the invention, these can then in turn be bonded to an aluminum oxide body, such as for example a sapphire.

Furthermore, it is expedient for the strength and optical quality of the bond for at least one the surfaces of the bodies intended to be joined together to be activated in particular with the formation of hydroxyl groups at the surface. The activation brings about direct chemical bonding with the aluminum/oxygen network which forms from the aluminate-containing bonding solution. In this context, a particular problem arises with bodies containing aluminum oxide. It has been found that these bodies cannot be sufficiently activated or cannot be activated at all with bases or acids. A high strength of the bond with a body of this type, however, has very surprisingly been achieved if peroxomonosulfuric acid was used for activation prior to the subsequent joining by means of the aluminate-containing solution. Accordingly, the invention also provides for the use of peroxomonosulfuric acid for treating bodies, in particular aluminum oxide bodies, for the low-temperature bonding of these bodies.

The process according to the invention therefore opens up a whole range of technological possibilities and new products. For example, it is possible for a plurality of aluminum oxide bodies, in particular sapphire bodies, to be joined together and bonded and then deformed in a zone melting process to form a sapphire crystal, in particular a sapphire single crystal. It is in this way possible to produce very large sapphire crystals, even in a size which has not hitherto been achieved as single crystals with dimensions of 4 inches and more. According to a refinement of the present invention, the bodies can also be deformed in a zone melting process to form a sapphire crystal, in particular a sapphire single crystal, with a larger diameter than the bodies which have been joined together. For this purpose, the substrates can, for example, be bonded one behind the other to form a rod-like substrate, and the rod formed in this way can then have its diameter increased during the zone melting. It is in this way also possible to produce a sapphire single crystal of a size of at least 4 inches in at least one direction, in particular with a diameter of this size.

The invention is suitable, inter alia, for the production of an optical component, such as a lens system, which comprises at least two optical bodies or elements or components which have been joined together in accordance with the invention and bonded with an aluminum/oxygen network. By way of example, according to the invention it is possible for sapphire windows to be bonded to further components by low-temperature bonding with a high strength and a high optical quality.

In the text which follows, the invention is explained in more detail on the basis of exemplary embodiments and with reference to the drawings, in which identical and similar elements are provided with the same reference designations and the features of various exemplary embodiments can be combined with one another.

### BRIEF DESCRIPTION OF THE SEVERAL VIEWS OF THE DRAWINGS

FIG. 1A to 1C show process steps involved in the production of a product according to the-invention,

FIG. 2 diagrammatically depicts a bond according to the invention,

FIG. 3 shows an exemplary embodiment with a plurality of sapphire crystals which have been bonded in accordance with the invention,

FIG. 4 shows a further exemplary embodiment for the production of sapphire crystals,

FIG. 5 shows a variant of the examples shown in FIG. 4.

### DETAILED DESCRIPTION OF THE INVENTION

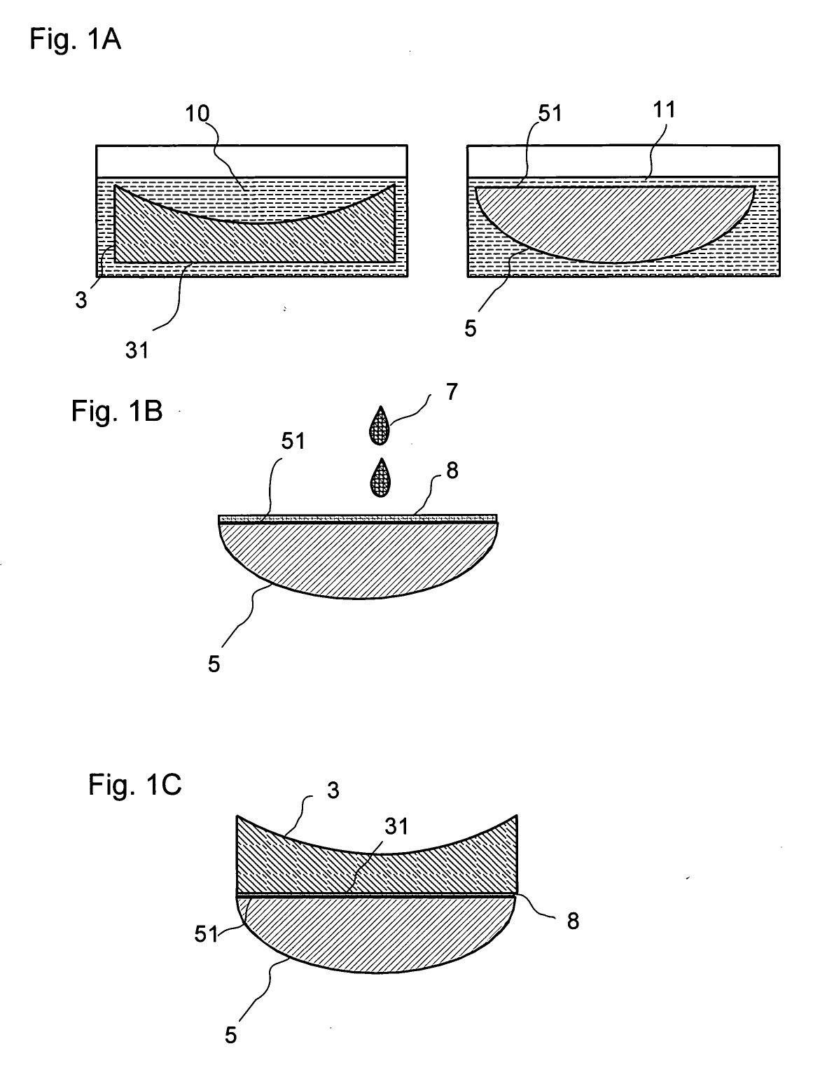

FIGS. 1A to 1C illustrate process steps used to produce a product according to the invention in accordance with one embodiment of the invention. Specifically, the production of a lens system comprising two joined-together bodies 3 and 5 is described.

The process for bonding the bodies 3, 5 is based on the bodies 3, 5 being joined together using an aluminate-containing solution and the aluminate-containing solution being made to react between those surfaces of the bodies which have been joined together. Each of the bodies 3, 5 has a surface 31 or 51, respectively, intended to be joined together. To obtain a stable bond, these surfaces are preferably polished in such a way that they have a flatness or planarity of better than 1 micrometer, preferably better than 200 nm. The polishing or the provision of polished bodies is followed by a cleaning procedure. In this context, it has proven advantageous inter alia to use carbon dioxide snow as cleaning agent, since this allows effective mechanical cleaning without the risk of the surfaces being scratched. Further cleaning agents, for example for degreasing the surfaces, are known to the person skilled in the art.

FIG. 1A illustrates a further preparatory step prior to the joining operation. To produce as many chemical bonds as possible to the surfaces 31, 51, the surfaces 31, 51 are activated so as to form hydroxyl groups at the surface. For this purpose, the surfaces 31, 51 are each treated with an activating agent 10, 11. In the example shown in FIG. 1A, different activating agents 10 and 11 are used for each of the bodies 3, 5. If the body materials are identical, it is of course also possible to use the same activating agents.

Examples of suitable activating agents for glass or glass-ceramic bodies include a potassium hydroxide solution, a potassium hydroxide melt, concentrated hydrochloric acid or nitric acid. According to the invention, peroxomonosulfuric acid is used for a sapphire body. This is obtained from a mixture of hydrogen peroxide and concentrated sulfuric acid and has proven greatly superior to other activating agents, such as the abovementioned bases or acids for activating the surface.

Following the treatment described above, the surfaces 31, 51 of the bodies 3, 5 are chemically reactive, so that chemical bonds can in turn form at the surface. By way of example, hydroxyl groups to which chemical bonding is possible can be formed by the activation at the surface. The activation can be checked, for example, by a wetting test: a small wetting angle of drops of water on the surface indicates a reactive surface with a large number of hydroxyl groups and demonstrates that the surface has been successfully activated. On the other hand, if a water droplet has poor wetting properties for the surface, i.e. the wetting angle of the droplet is in particular more than 30°, the surface is relatively unreactive, which is disadvantageous for the strength of the low-temperature bond to be produced.

Following the activation, as illustrated in FIG. 1B, a tetrahydroxyaluminate solution is applied to that surface 51 of one of the bodies 5 which is to be bonded, so that a thin liquid film 8 of the coating solution is formed on this surface. To prevent the aluminate from precipitating out, the solution also contains a base to stabilize it. A sodium aluminate solution stabilized with sodium hydroxide has proven particularly suitable. The tetrahydroxyaluminate is formed in the solution according to the following reaction equation:
NaAlO₂+2H₂O [symbol] Na[Al(OH)₄].

Then, as shown in FIG. 1C, the bodies 3 and 5 are joined together by way of the sides 31, 51 that are to be bonded, by being placed on top of one another. Next, a chemical reaction takes place in the liquid film 8 comprising the aluminate solution, forming the aluminum/oxygen network. Both the steps of joining and of chemically reacting the aluminate-containing solution take place at low temperatures. The joining takes place in particular at temperatures of less than 100° C., particularly preferably at room temperature, while temperatures between room temperature and approximately 200° C., in particular up to 100° C., are suitable for the chemical reaction.

During the chemical reaction, which is carried out for example in a moderately heated furnace of a climate chamber, an aluminum/oxygen network is formed and the network is bonded to reactive groups at the surface of the activated surfaces 31, 51 of the bodies 3, 5. The water which is present is partially evaporated at the edges of the bond and also partially diffuses into the bodies, depending on the nature of the bodies.

For example, if carbon dioxide snow was used to clean the bodies, it is also advantageous for the atmosphere to be exchanged for a low-carbon dioxide atmosphere prior to the bodies being joined, in order to prevent relatively large quantities of carbonic acid forming in the bonding solution 7 or the liquid film 8. This is expedient since it has surprisingly emerged that the presence of carbonic acid is extremely disadvantageous to the strength and optical quality of the bond.

In the product which is ultimately obtained in the form of an optical component, in the example shown here in particular a lens system comprising two optical bodies 3, 5, in particular at least one of the bodies 3, 5 may be a body which contains aluminum oxide. By way of example, an aluminum oxide ceramic or in particular also a sapphire body is suitable in this context. By way of example, it is also possible for a sapphire body to be bonded to an aluminum oxide ceramic body, so that both bodies 3 and 5 contain aluminum oxide.

However, the process according to the invention also allows the bonding of other materials, such as silicate or phosphate glasses, glass-ceramics or crystalline materials. By way of example, therefore, according to the invention it is possible for a sapphire lens or a sapphire window to be bonded to another component made from glass. Therefore, by combining suitable materials it is also possible to create optics for the infrared region.

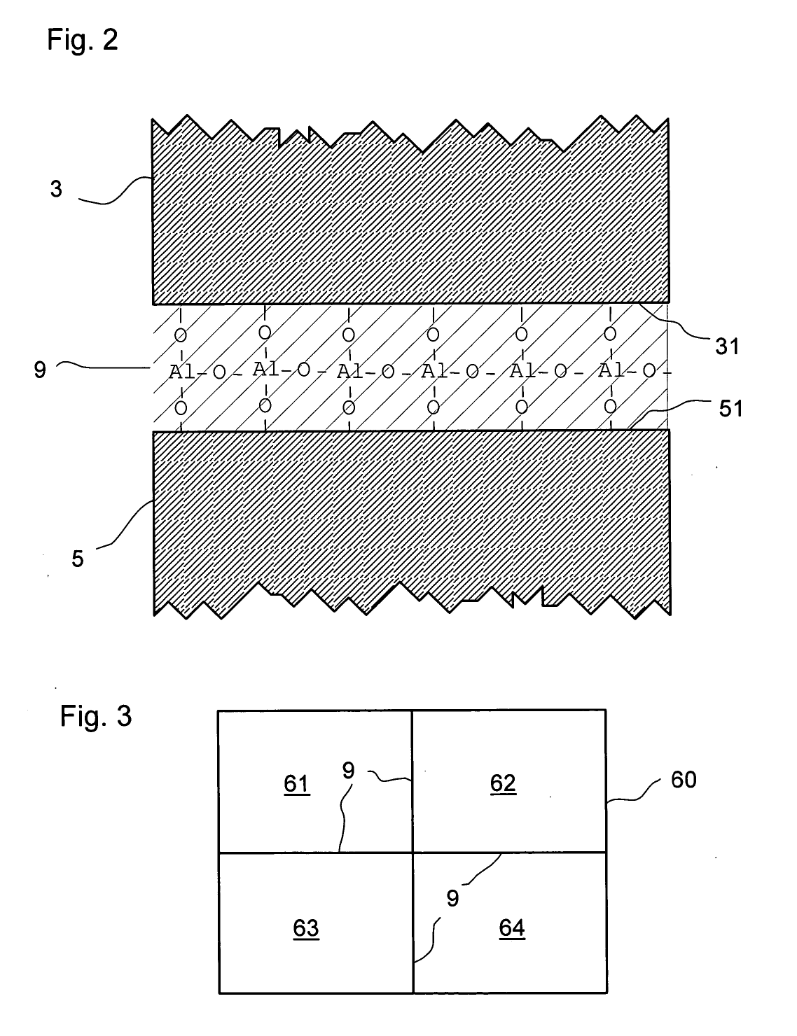

The bond according to the invention which is formed between the bodies 3, 5 is diagrammatically depicted in FIG. 2. In the spaces which remain between the surfaces 31, 51, a bond 9 comprising a high-strength and a high-temperature-resistant aluminum/oxygen network is formed, which is also chemically bonded or crosslinked to atoms of the surfaces, as indicated by the bond lines directed toward the surfaces 31, 51. This creates a low-temperature bond with a very high strength and optical quality and a thermal stability which is comparable to that of sapphire or pure aluminum oxide, even though further constituents of the bonding solution, such as for example sodium ions (not shown) from the sodium hydroxide added for stabilization purposes, are still contained in the network.

FIG. 3 illustrates a further exemplary embodiment of bodies which have been bonded in accordance with the invention. In this exemplary embodiment, a plurality of sapphire single crystals 61, 62, 63, 64 have been joined together to form a larger sapphires crystal 60 by means of bonds 9 producible in accordance with the invention by low-temperature bonding using an aluminate-containing solution. According to an advantageous refinement, the sapphire single crystals are joined together in such a way that the crystal orientations coincide. It is in this case readily possible, for example, to achieve dimensions of more than 4 inches in the diameter of the crystal 60.

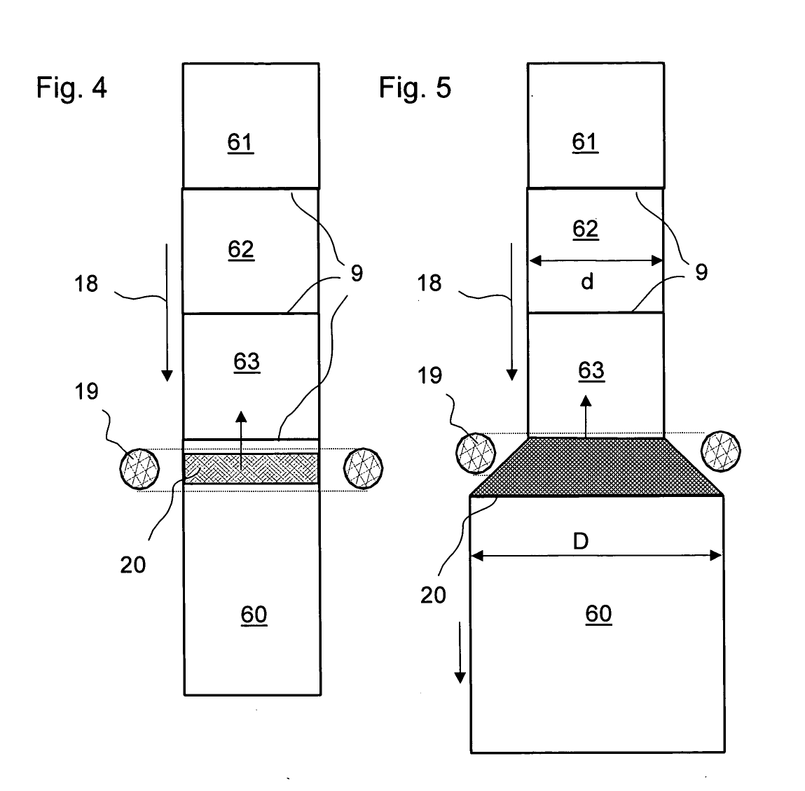

FIG. 4 shows a further exemplary embodiment for the production of larger sapphire crystals. In this example, a plurality of aluminum oxide bodies 61, 62, 63 have been joined together according to the invention by means of low-temperature bonding to form a rod. The bodies may, for example, be polycrystalline or single-crystal sapphire. The rod obtained in this way is then deformed in a zone melting process to produce a sapphire crystal, in particular a sapphire single crystal. In this case, the rod is guided along a direction of advance 18 through a heating apparatus 19 which locally melts the rod in a melting zone 20. The movement in the direction 18 causes the melting zone 20 to progress through the rod. The material which escapes is in the process deformed to produce a single crystal 60 which has been fused together from the individual bodies 61, 62, 63. Of course, it is also possible for the rod to be held in a stationary position and the heating apparatus 19 to be moved along the rod. Since any desired number of bodies can be joined together in a row by means of low-temperature bonding in accordance with the invention, the invention allows the growth of very long sapphire crystals, in particular including sapphire single crystals.

FIG. 5 shows a variant of the example shown in FIG. 4. In this variant, the bodies 61, 62, 63 are deformed in a zone melting process to give a sapphire crystal 60, in particular a sapphire single crystal, which has been deformed to have a larger diameter than the bodies 61, 62, 63 which were joined together in succession to form a rod. For this purpose, the sapphire crystal 60 which is formed after it has passed through the melting zone 20 is moved at a lower rate of advance than the bodies 61, 62, 63 which have been joined together. The melting zone 20 in this case widens starting from diameter d of the joined-together bodies 61, 62, 63 to the diameter D of the sapphire crystal 60 produced from these bodies in the zone melting process.

To allow a significant change in the diameter to be achieved, the rates of advance must be correspondingly different. In particular, a rather long rod of starting bodies is then required in order to obtain a crystal 60 of sufficient length or even to enable the process to be carried out at all. The invention for the first time makes it possible to produce a sufficiently long rod of aluminum oxide bodies, in particular sapphire crystals, arranged in a row which are then remelted in the process shown with reference to FIG. 4 or 5. Bonds which have previously been known, such as for example silicate-based low-temperature bonds, would melt and become detached before the bodies melt. By contrast, the bonds according to the invention have a similar thermal stability to the sapphire crystals 60, 61, 62, 63 and allow the production of sapphire crystals of great length and/or a large diameter as outline above.

Therefore, the process illustrated in FIG. 5 can readily be used to obtain sapphire bodies with a diameter D of 4 inches and more.

It will be clear to the person skilled in the art that the invention is not restricted to the embodiments described above, but rather can be varied in numerous ways. In particular, it is also possible for the features of the individual exemplary embodiments to be combined with one another.

1. A process for bonding surfaces of at least two bodies, comprising:
applying an aluminate-containing solution on one of the surfaces to be joined;
placing the surfaces to be joined on top of one another; and
reacting constituents of the aluminate-containing solution between the surfaces.

2. The process as claimed in claim 1, wherein the aluminate-containing solution comprises a tetrahydroxyaluminate-containing solution.

3. The process as claimed in claim 1, wherein the aluminate-containing solution is stabilized with a base.

4. The process as claimed in claim 3, wherein the aluminate-containing solution comprises a sodium aluminate solution and the base comprises sodium hydroxide.

5. The process as claimed in claim 1, wherein placing the surfaces on top of one another further comprises maintaining the at least two bodies at a temperature of less than 100° C.

6. The process as claimed in claim 1, wherein reacting the constituents of the aluminate-containing solution comprises reacting the constituents at a temperature in the range up to 200° C.

7. The process as claimed in claim 1, further comprising polishing the surfaces to a planarity of less than 1 micrometer.

8. The process as claimed in claim 1, further comprising polishing the surfaces to a planarity of less than 200 nm.

9. The process as claimed in claim 1, further comprising using bodies having surfaces that have a planarity of less than 200 nm.

10. The process as claimed in claim 1, further comprising activating the surfaces to form hydroxyl groups at the surfaces before applying the aluminate-containing solution.

11. The process as claimed in claim 1, further comprising treating at least one of the surfaces with peroxomonosulfuric acid before applying the aluminate-containing solution.

12. The process as claimed in claim 11, wherein at least one of the at least two bodies comprises aluminum oxide.

13. The process as claimed in claim 1, wherein at least one of the at least two bodies comprises a sapphire body.

14. The process as claimed in claim 1, wherein the at least two bodies comprise sapphire single-crystal bodies that form a larger crystal by being joined together.

15. The process as claimed in claim 14, further comprising deforming the larger crystal using a zone-melting process to form a sapphire single crystal.

16. The process as claimed in claim 15, wherein the sapphire single crystal has a larger diameter than the at least two bodies that have been joined together.

17. The process as claimed in claim 1, wherein the at least two bodies comprise glass bodies and once joined together produce an optical component.

18. The process as claimed in claim 1, wherein the steps of placing the surfaces to be joined on top of one another and/or reacting constituents of the aluminate-containing solution between the surfaces is/are carried out in a low-carbon dioxide atmosphere.

19. A sapphire single crystal comprising a size of at least 4 inches in at least one direction.

20. The sapphire single crystal as claimed in claim 19, wherein the size comprises a diameter of at least 4 inches.

21. A solution for the low-temperature bonding of bodies, comprising an aluminate-containing solution.

22. The solution as claimed in claim 21, wherein the aluminate-containing solution comprises tetrahydroxy aluminate.

23. The solution as claimed in claim 21, further comprising a base stabilizing the aluminate-containing solution.

24. The solution as claimed in claim 23, wherein the aluminate-containing solution comprises sodium aluminate and the base comprises sodium hydroxide.

25. A product comprising:
at least two bonded bodies, wherein a first surface of one of the at least two bonded bodies is bonded to a second surface of another of the at least two bonded bodies by an aluminum-oxygen network.

26. The product as claimed in claim 25, wherein the first and second surfaces comprise polished surfaces.

27. The product as claimed in claim 25, wherein the first and second surfaces comprise a planarity of less than 1 micrometer.

28. The product as claimed in claim 25, wherein the first and second surfaces comprise a planarity of less than 200 nm.

29. The product as claimed in claim 25, wherein at least one of the at least two bonded bodies comprises aluminum oxide.

30. The product as claimed in claim 25, wherein at least one of the at least two bonded bodies is a sapphire crystal or an aluminum oxide ceramic.

31. The product as claimed in claim 25, wherein the at least two bonded bodies comprises a sapphire single crystal having a size of at least 4 inches in one direction.

32. The product as claimed in claim 25, wherein the product finds use as an optical component.

33. The product as claimed in claim 25, wherein the product finds use as lens system with at least two optical bodies bonded by means of the aluminum-oxygen network.

34. The product as claimed in claim 25, wherein at least one of the at least two bonded bodies is a glass or glass-ceramic body or a crystalline material.

35. A method of activating surfaces of aluminum oxide bodies for the low-temperature bonding of such bodies comprising: using peroxomonosulfuric acid of the surfaces.
